(19) United States
(12) Patent Application Publication
(10) Pub. No.: US 2025/0043797 A1
(43) Pub. Date: Feb. 6, 2025

(54) WHEELS INCLUDING AN ALUMINUM ALLOY AND METHODS FOR MAKING THE SAME

(71) Applicant: Garrett Transportation I Inc., Torrance, CA (US)

(72) Inventors: Brent Donato, Torrance, CA (US); Dana Bocci, Torrance, CA (US); Ryoken Matsuzaki, Torrance, CA (US)

(73) Assignee: Garrett Transportation I Inc., Torrance, CA (US)

(21) Appl. No.: 18/410,364

(22) Filed: Jan. 11, 2024

Related U.S. Application Data
(60) Provisional application No. 63/517,577, filed on Aug. 3, 2023.

(51) Int. Cl. F04D 29/28; C22C 21/10

(52) U.S. Cl. CPC F04D 29/285; C22C 21/10; F05D 2220/40; F05D 2300/121

(57) ABSTRACT

A wheel includes a hub portion configured to rotate about a rotational axis. A plurality of blades extends radially outward from the hub portion. Each blade of the plurality of blades includes a leading edge and a trailing edge. The hub portion and the plurality of blades include a substrate metal. The substrate metal includes an aluminum alloy. The aluminum alloy includes, by weight, about 0% to about 0.12% silicon, about 0% to about 0.15% iron, about 1.6% to about 2.4% copper, about 0% to about 0.1% manganese, about 2.2% to about 3.0% magnesium, about 0% to about 0.05% chromium, about 7.3% to about 8.3% zinc, about 0% to about 0.1% titanium, about 0.05% to about 0.15% zirconium, and a balance of aluminum, and other inevitable/unavoidable impurities that are present in trace amounts.

### CROSS-REFERENCE TO RELATED APPLICATIONS

This application is related to and claims all available benefit of U.S. Provisional Patent Application 63/517,577 filed Aug. 3, 2023, the entire contents of which are herein incorporated by reference.

### TECHNICAL FIELD

The present disclosure generally relates to wheels for turbo-devices, for example, turbochargers, turbines or turbomachines, and/or the like. More particularly, the present disclosure relates to wheels including or otherwise formed of an aluminum alloy having enhanced erosion resistance and methods for making the same.

### BACKGROUND

Turbo-devices can be used in a variety of applications. For example, turbochargers for gasoline and diesel internal combustion engines are devices known in the art that are used for pressurizing or boosting the intake air stream, routed to a combustion chamber of the engine, by using the heat and volumetric flow of exhaust gas exiting the engine. Another example includes turbines or turbomachines for fuel cells. The turbine may be operatively connected to a fuel cell system and may be configured as an e-charger, electric turbocharger, or other turbo-device for the fuel cell.

In the case of turbochargers for internal combustion engines, the exhaust gas exiting the engine is routed into a turbine housing of a turbocharger in a manner that causes an exhaust gas-driven turbine wheel to spin within the housing. The exhaust gas-driven turbine wheel is mounted onto one end of a shaft that is common to a radial air compressor mounted onto an opposite end of the shaft and housed in a compressor housing. Thus, rotary action of the turbine wheel also causes the air compressor to spin within a compressor housing of the turbocharger that is separate from the turbine housing. The spinning action of the air compressor causes intake air to enter the compressor housing and be pressurized or boosted to a desired amount before it is mixed with fuel and combusted within the engine combustion chamber.

In recent years, there has been increasing pressure in the form of governmental legislation to reduce internal combustion engine emissions, such as NOₓ and particulate matter (PM). Oxides of nitrogen (NOₓ) may be formed when temperatures in the combustion chamber are about 2500° F. or hotter. At these elevated temperatures, the nitrogen and oxygen in the combustion chamber may chemically combine to form nitrous oxides.

Exhaust gas recirculation (EGR) is a method that has been used to reduce the level of NOₓ in exhaust gases. In EGR systems, some of the exhaust gases that would otherwise be discharged into the environment are recirculated into the intake stream. The recirculated exhaust gases have already combusted and have a significantly lower oxygen content, so they do not burn again when they are recirculated. The exhaust gases may displace some of the normal intake charge. As a result, the combustion process may be cooler by several hundred degrees so that NOₓ formation may be reduced.

The use of EGR, however, results in an increased amount of water that is condensed out of the recirculated exhaust gases. The amount of water that is condensed may depend, for example, on temperature, humidity, and operating speed of the engine. When present, the condensed water droplets in the intake stream are passed through an inlet and impact the spinning compressor wheel, and as a result, an erosive effect may be observed over time. This can cause the components to prematurely fail.

Similarly in turbines for fuel cells, when present, condensed water droplets in the intake stream are passed through an inlet and impact the spinning fuel cell turbine wheel, and as a result, an erosive effect may also be observed over time. As a result, such components as well may prematurely fail.

Accordingly, it is desirable to provide wheels for turbo-devices that are able to withstand the erosive effects of water droplets, without requiring the use of heavier and relatively expensive materials. Furthermore, other desirable features and characteristics of the inventive subject matter will become apparent from the subsequent detailed description of the inventive subject matter and the appended claims, taken in conjunction with the accompanying drawings and this background of the inventive subject matter.

### BRIEF SUMMARY

Wheels having enhanced erosion resistance and methods for making the same, are disclosed herein.

In an exemplary embodiment, a wheel includes a hub portion configured to rotate about a rotational axis. A plurality of blades extend radially outward from the hub portion. Each blade of the plurality of blades includes a leading edge and a trailing edge. The hub portion and the plurality of blades are formed of a substrate metal that includes an aluminum alloy. The aluminum alloy includes, by weight, about 0% to about 0.12% silicon, about 0% to about 0.15% iron, about 1.6% to about 2.4% copper, about 0% to about 0.1% manganese, about 2.2% to about 3.0% magnesium, about 0% to about 0.05% chromium, about 7.3% to about 8.3% zinc, about 0% to about 0.1% titanium, about 0.05% to about 0.15% zirconium, and a balance of aluminum, and other inevitable/unavoidable impurities that are present in trace amounts.

In another exemplary embodiment, a wheel includes a hub portion configured to rotate about a rotational axis. A plurality of blades extend radially outward from the hub portion. Each blade of the plurality of blades includes a leading edge and a trailing edge. The hub portion and the plurality of blades are formed of a substrate metal that includes an aluminum alloy. The aluminum alloy includes, by weight, about 0% to about 0.12% silicon, about 0% to about 0.15% iron, about 1.6% to about 2.4% copper, about 0% to about 0.1% manganese, about 2.2% to about 3.0% magnesium, about 0% to about 0.05% chromium, about 7.3% to about 8.3% zinc, about 0% to about 0.1% titanium, about 0.05% to about 0.15% zirconium, and a balance of aluminum, and other inevitable/unavoidable impurities that are present in trace amounts. The plurality of blades each have an outer surface extending between the leading and trailing edges that is exposed and free of any coatings and that is formed of the aluminum alloy. The aluminum alloy has a Brinell hardness of about 170 or greater, a yield tensile strength (YTS) independently in a longitudinal direction and a transverse direction of about 70 ksi or greater, and ultimate tensile strength (UTS) independently in the longitudinal direction and the transverse direction of about 80 ksi or greater for enhanced erosion resistance.

In another exemplary embodiment, a method for making a wheel includes providing a substrate metal including an aluminum alloy. The aluminum alloy includes, by weight, about 0% to about 0.12% silicon, about 0% to about 0.15% iron, about 1.6% to about 2.4% copper, about 0% to about 0.1% manganese, about 2.2% to about 3.0% magnesium, about 0% to about 0.05% chromium, about 7.3% to about 8.3% zinc, about 0% to about 0.1% titanium, about 0.05% to about 0.15% zirconium, and a balance of aluminum, and other inevitable/unavoidable impurities that are present in trace amounts. The method further includes forming the wheel including a hub portion configured to rotate about a rotational axis and a plurality of blades extending radially outward from the hub portion. Each blade of the plurality of blades includes a leading edge and a trailing edge. The hub portion and the plurality of blades are formed of the substrate metal.

This summary is provided to introduce a selection of concepts in a simplified form that are further described below in the detailed description. This summary is not intended to identify key features or essential features of the claimed subject matter, nor is it intended to be used as an aid in determining the scope of the claimed subject matter.

### BRIEF DESCRIPTION OF THE DRAWINGS

The inventive subject matter will hereinafter be described in conjunction with the following drawing figures, wherein like numerals denote like elements, and wherein:

FIG. 1 is a perspective view of a wheel operatively disposed in a turbo-device, which is schematically illustrated, in accordance with some embodiments of the present disclosure;

FIG. 2 is a perspective view of a wheel operatively disposed in a turbo-device, which is schematically illustrated, in accordance with some embodiments of the present disclosure; and

FIG. 3 is a flowchart illustrating a method for making a wheel in accordance with some embodiments of the present disclosure.

### DETAILED DESCRIPTION

The following detailed description is merely exemplary in nature and is not intended to limit the invention or the application and uses of the invention. As used herein, the word “exemplary” means “serving as an example, instance, or illustration.” Thus, any embodiment described herein as “exemplary” is not necessarily to be construed as preferred or advantageous over other embodiments. All of the embodiments described herein are exemplary embodiments provided to enable persons skilled in the art to make or use the invention and not to limit the scope of the invention which is defined by the claims. Furthermore, there is no intention to be bound by any expressed or implied theory presented in the preceding technical field, background, brief summary, or the following detailed description.

Unless specifically stated or obvious from context, as used herein, the term “about” is understood as within a range of normal tolerance in the art, for example within 2 standard deviations of the mean. “About” can be understood as within 10%, 5%, 1%, 0.5%, 0.1%, 0.05%, or 0.01% of the stated value. “About” can alternatively be understood as implying the exact value stated. Unless otherwise clear from the context, all numerical values provided herein are modified by the term “about.”

The present disclosure is generally directed to wheels for turbo-devices in which the wheels have enhanced erosion resistance and methods for making the same. In particular, the present disclosure addresses the aforementioned erosion problem with the use of a wheel having a hub and blades extending therefrom that are formed of an aluminum alloy having relatively high hardness, strength and durability as compared to conventional wheels formed of aluminum 2618 alloy or other like softer aluminum alloys, which require a relatively hard coating formed thereon in order to provide some level of erosion resistance. In an exemplary embodiment, the aluminum alloy is designated as an aluminum 7068 alloy and includes or consist of, by weight, about 0% to about 0.12% silicon, about 0% to about 0.15% iron, about 1.6% to about 2.4% copper, about 0% to about 0.1% manganese, about 2.2% to about 3.0% magnesium, about 0% to about 0.05% chromium, about 7.3% to about 8.3% zinc, about 0% to about 0.1% titanium, about 0.05% to about 0.15% zirconium, and a balance of aluminum, and other inevitable/unavoidable impurities that are present in trace amounts. In an exemplary embodiment, the alloy includes about 1.8% to about 2.2% copper, about 2.4% to about 2.8% magnesium, about 7.5% to about 8.1% zinc, and about 0.07% to about 0.13% zirconium.

In an exemplary embodiment, the aluminum alloy has been heat treated and tempered according to the code designation T6/T6511 to further enhance its hardness, strength and durability as compared to aluminum 2618 alloy or other like softer aluminum alloys. In particular, a temper code designation of T6511 is understood to mean an aluminum alloy has been solution heat treated and stress-relieved by stretching, then artificially aged with minor straightening after aging. Solution heat treating is understood to mean the process of heating an aluminum alloy at a prescribed temperature for a prescribed time and then cooling rapidly by quenching in water. An artificial aging designation of T6 is understood to mean a process of heating an aluminum alloy for the prescribed period of from about 2 hours to about 30 hours at the prescribed temperature of from about 100° C. to about 200° C. until the alloy reaches a stable condition, thereby increasing hardness and strength after solution heat treating.

In one embodiment, the aluminum alloy has a Brinell hardness of about 170 or greater, a yield tensile strength (YTS) independently in a longitudinal direction and in a transverse direction of about 70 ksi or greater, and ultimate tensile strength (UTS) independently in the longitudinal direction and in the transverse direction of about 80 ksi or greater for enhanced erosion resistance. TABLE 1, set forth below, provides various properties for aluminum 7068 alloy with a T6511 temper compared to conventional aluminum 2618 alloy with a T6511 temper:

TABLE 1
Aluminum 7068 vs. 2618 Alloys

| | 7068-T6511 | 2618-T6511 |
|---|---|---|
| Spec | N/A | IDM-4295 |
| Brinell Hardness | 190 | 115 |
| Rockwell B Hardness | 91 | 72 |
| YTS (KSI) | 95 (longitudinal) | 47 |
| UTS (KSI) | 78 (short transverse) | 58 |
| | 99 (longitudinal) | |
| | 87 (short transverse) | 5 |
| Elongation (%) | 5 | |
| Young's Modulus | 10.1 | 10.8 |
| (10\hat{ }3 KSI) | | |

As discussed above, the wheel is formed of the aluminum 7068 alloy that has a relatively high hardness, strength, and durability. By providing this additional hardness, strength and durability as compared to conventional wheels formed of softer aluminum alloys, helps the wheel including particularly the blades to withstand the erosive effects of water droplets, without requiring the use of any coatings or other heavier and relatively expensive materials.

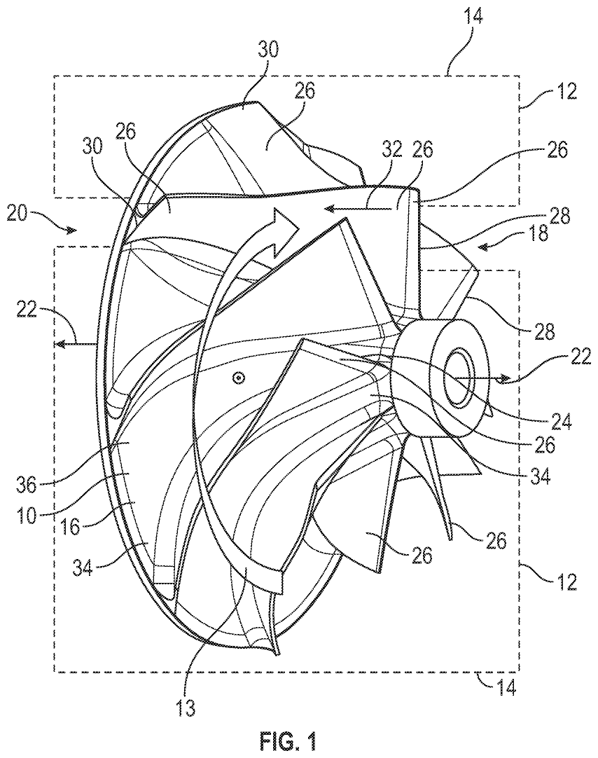

Referring to FIG. 1, a perspective view of a wheel 10 operatively disposed in a turbo-device 12 is provided. In the illustrated embodiment, the turbo-device 12 is configured as a turbocharger 14 for an internal combustion engine and the wheel 10 is configured as a turbocharger compressor wheel 16. A non-limiting example of turbochargers for internal combustion engines including turbocharger compressor wheels is described in U.S. Pat. No. 11,566,631, filed on Mar. 29, 2021, which is owned by the assignee of the present application and is hereby incorporated by reference in its entirety for all purposes.

As illustrated, the wheel 10 is operatively disposed in the turbo-device 12 between an inlet 18 and an outlet 20 to rotate (indicated by single headed arrow 13) about a rotational axis 22. The wheel 10 is a radial wheel that includes a hub portion 24 and a plurality of blades 26 that extend radially outward from the hub portion 24. The blades 26 have a backward curvature rather than being configured to extend in a purely radial blade configuration. Each blade 26 includes a leading edge 28 that is in fluid communication with the inlet 18 and a trailing edge 30 that is in fluid communication with the outlet 20. The leading edges 28 define the beginning of an intake area for the combined set of blades 26, extending through the circular paths of roughly the upstream ⅓ of the blades 26. The trailing edges 30 define the end of an annular output area for the combined set of blades 26, extending through the circular paths of roughly the downstream ⅓ of the blades 26.

During operation of the turbo-device 12, the wheel 10 rotates about the rotational axis 22 and the leading edges 28 receive intake air that passes through the inlet 18 and advances rearwardly (indicated by single headed arrow 32) along the blades 26 towards the trailing edges 30. As such, the leading edges 28 are positioned longitudinally forward of the trailing edges 30 of the blades 26 with respect to the rotational axis 22 and the flow of air 32 along the wheel 10. As noted above, the wheel 10 is a turbocharger compressor wheel 16 in which the blades 26 are configured to compress the intake air to form compressed or pressurized air. The pressurized air passes from the trailing edges 30 and is ejected out through the outlet 20.

In an exemplary embodiment, the hub portion 24 and the blades 26 are formed of a substrate metal 36 that is formed of, includes, or otherwise consists of the aluminum 7068 alloy as discussed above, for example, via a machining process. In an exemplary embodiment, the hub portion 24 and the plurality of blades 26 together form a monolithic structure. As illustrated, the plurality of blades 26 each have an outer surface 34 extending between the leading and trailing edges that is exposed and formed of the aluminum 7068 alloy and that is free of any coatings.

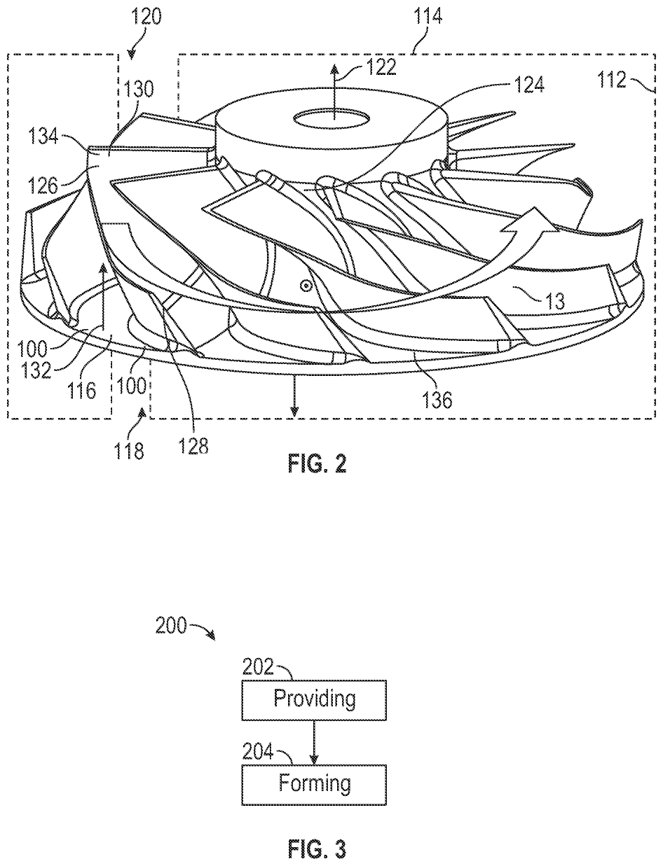

Referring to FIG. 2, a wheel 100 that is operatively disposed in a turbo-device 112 between an inlet 118 and an outlet 120 is provided. In the illustrated embodiment, the turbo-device is a turbine 114 for fuel cells and the wheel 100 is configured as a fuel cell turbine wheel 116. A non-limiting example of turbines for fuel cells including fuel cell turbine wheels is described in U.S. Patent Application Publication No. 2022/0006369, filed on Jul. 1, 2020, which is owned by the assignee of the present application and is hereby incorporated by reference in its entirety for all purposes.

In particular, the wheel 100 including the rotational axis 122, the hub portion 124, the blades 126, the leading edges 128, the trailing edges 130, and the substrate metal 136 formed of the aluminum 7068 alloy including the outer surfaces 134 are similarly configured to the wheel 10 as discussed above in relation to FIG. 1 including the rotational axis 22, the hub portion 24, the blades 26, the leading edges 28, the trailing edges 30, and the substrate metal 36 including the outer surfaces 34, respectively, but with the exception that the blades 126 are configured to expand the intake air received from the inlet 118, along the airflow direction 132 towards the trailing edges 130 to form an expanded or depressurized air. The expanded or depressurized air passes from the trailing edges 130 and is ejected out through the outlet 120.

Referring to FIG. 3, the compressor wheel 10, 100 as discussed above may be made in accordance with a method 200 as illustrated in the flowchart. The method 200 includes providing (STEP 202) a substrate metal including the aluminum 7068 alloy as discussed above. In an exemplary embodiment, the substrate metal is provided in a bar stock form that has been heat treated and tempered according to the code designation of T6/T6511.

The method further includes forming (STEP 204) the wheel including a hub portion configured to rotate about a rotational axis and a plurality of blades extending radially outward from the hub portion. Each blade of the plurality of blades comprises a leading edge and a trailing edge. The hub portion and the plurality of blades are formed of the substrate metal. In an exemplary embodiment, the wheel is formed by machining the bar stock to form the hub portion and the plurality of blades extending radially outward from the hub portion.

The method 200 may include performing various finishing processes, such as final cleaning, polishing, and/or the like. The result is a wheel 10, 100 in accordance with that described above in connection with FIGS. 1-2.

While at least one exemplary embodiment has been presented in the foregoing detailed description of the inventive subject matter, it should be appreciated that a vast number of variations exist. It should also be appreciated that the exemplary embodiment or exemplary embodiments are only examples, and are not intended to limit the scope, applicability, or configuration of the inventive subject matter in any way. Rather, the foregoing detailed description will provide those skilled in the art with a convenient road map for implementing an exemplary embodiment of the inventive subject matter. It being understood that various changes may be made in the function and arrangement of elements described in an exemplary embodiment without departing from the scope of the inventive subject matter as set forth in the appended claims.

1. A wheel comprising:
a hub portion configured to rotate about a rotational axis; and
a plurality of blades extending radially outward from the hub portion, wherein each blade of the plurality of blades comprises a leading edge and a trailing edge,
wherein the hub portion and the plurality of blades are formed of a substrate metal comprising an aluminum alloy that comprises, by weight:
about 0% to about 0.12% silicon;
about 0% to about 0.15% iron;
about 1.6% to about 2.4% copper;
about 0% to about 0.1% manganese;
about 2.2% to about 3.0% magnesium;
about 0% to about 0.05% chromium;
about 7.3% to about 8.3% zinc;
about 0% to about 0.1% titanium;
about 0.05% to about 0.15% zirconium; and
a balance of aluminum, and other inevitable/unavoidable impurities that are present in trace amounts.

2. The wheel of claim 1, wherein the aluminium alloy comprises about 1.8% to about 2.2% copper.

3. The wheel of claim 1, wherein the aluminium alloy comprises about 2.4% to about 2.8% magnesium.

4. The wheel of claim 1, wherein the aluminium alloy comprises about 7.5% to about 8.1% zinc.

5. The wheel of claim 1, wherein the aluminium alloy comprises about 0.07% to about 0.13% zirconium.

6. The wheel of claim 1, wherein the aluminium alloy consist of, by weight:
about 0% to about 0.12% silicon;
about 0% to about 0.15% iron;
about 1.6% to about 2.4% copper;
about 0% to about 0.1% manganese;
about 2.2% to about 3.0% magnesium;
about 0% to about 0.05% chromium;
about 7.3% to about 8.3% zinc;
about 0% to about 0.1% titanium;
about 0.05% to about 0.15% zirconium; and
a balance of aluminum, and other inevitable/unavoidable impurities that are present in trace amounts.

7. The wheel of claim 1, wherein the hub portion and the plurality of blades together form a monolithic structure.

8. The wheel of claim 1, wherein the plurality of blades each have an outer surface extending between the leading and trailing edges that is exposed and formed of the aluminium alloy.

9. The wheel of claim 8, wherein the outer surfaces are free of any coatings.

10. The wheel of claim 1, wherein the aluminium alloy has a Brinell hardness of about 170 or greater for enhanced erosion resistance.

11. The wheel of claim 1, wherein the aluminium alloy has a yield tensile strength (YTS) independently in a longitudinal direction and in a transverse direction of about 70 ksi or greater and ultimate tensile strength (UTS) independently in the longitudinal direction and the transverse direction of about 80 ksi or greater for enhanced erosion resistance.

12. The wheel of claim 1, wherein the wheel is configured as a turbocharger compressor wheel or a fuel cell turbine wheel.

13. A wheel comprising:
a hub portion configured to rotate about a rotational axis; and
a plurality of blades extending radially outward from the hub portion, wherein each blade of the plurality of blades comprises a leading edge and a trailing edge,
wherein the hub portion and the plurality of blades are formed of a substrate metal comprising an aluminum alloy that comprises, by weight:
about 0% to about 0.12% silicon;
about 0% to about 0.15% iron;
about 1.6% to about 2.4% copper;
about 0% to about 0.1% manganese;
about 2.2% to about 3.0% magnesium;
about 0% to about 0.05% chromium;
about 7.3% to about 8.3% zinc;
about 0% to about 0.1% titanium;
about 0.05% to about 0.15% zirconium; and
a balance of aluminum, and other inevitable/unavoidable impurities that are present in trace amounts, wherein the plurality of blades each have an outer surface extending between the leading and trailing edges that is exposed and free of any coatings and that is formed of the aluminum alloy, and wherein the aluminum alloy has a Brinell hardness of about 170 or greater, a yield tensile strength (YTS) independently in a longitudinal direction and a transverse direction of about 70 ksi or greater, and ultimate tensile strength (UTS) independently in the longitudinal direction and the transverse direction of about 80 ksi or greater for enhanced erosion resistance.

14. A method for making a wheel, the method comprising:
providing a substrate metal comprising an aluminum alloy that comprises, by weight:
about 0% to about 0.12% silicon;
about 0% to about 0.15% iron;
about 1.6% to about 2.4% copper;
about 0% to about 0.1% manganese;
about 2.2% to about 3.0% magnesium;
about 0% to about 0.05% chromium;
about 7.3% to about 8.3% zinc;
about 0% to about 0.1% titanium;
about 0.05% to about 0.15% zirconium; and
a balance of aluminum, and other inevitable/unavoidable impurities that are present in trace amounts; and
forming the wheel comprising:
a hub portion configured to rotate about a rotational axis; and
a plurality of blades extending radially outward from the hub portion, wherein each blade of the plurality of blades comprises a leading edge and a trailing edge, and wherein the hub portion and the plurality of blades are formed of the substrate metal.

15. The method of claim 14, wherein providing comprises providing the substrate metal in a bar stock form, and wherein forming the wheel comprises machining the bar stock to form the hub portion and the plurality of blades extending radially outward from the hub portion.

16. The method of claim 15, wherein providing comprises providing the bar stock that has been heat treated and tempered according to a code designation of T6/T6511.

17. The method of claim 14, wherein forming the wheel comprises forming the hub portion and the plurality of blades together as a monolithic structure.

18. The method of claim 14, wherein forming the wheel comprises forming the plurality of blades each having an outer surface extending between the leading and trailing edges that is exposed and formed of the aluminium alloy.

19. The method of claim 18, wherein the outer surfaces are free of any coatings.

20. The method of claim 14, wherein providing the substrate metal comprises providing the aluminium alloy having a Brinell hardness of about 170 or greater, a yield tensile strength (YTS) independently in a longitudinal direction and a transverse direction of about 70 ksi or greater, and ultimate tensile strength (UTS) independently in the longitudinal direction and the transverse direction of about 80 ksi or greater for enhanced erosion resistance.
